(19) United States
(12) Patent Application Publication
(10) Pub. No.: US 2006/0191709 A1
(43) Pub. Date: Aug. 31, 2006

(54) Printed circuit board, flip chip ball grid array board and method of fabricating the same

(75) Inventors: Hong Won Kim, Chungcheongbuk-do (KR); Seung Chul Kim, Chungcheongbuk-do (KR); Chang Hyun Nam, Chungcheongbuk-do (KR)

Correspondence Address: DARBY & DARBY P.C., P. O. BOX 5257, NEW YORK, NY, 10150-5257, US

(73) Assignee: Samsung Electro-Mechanics Co., Ltd., Gyeonggi-do (KR)

(21) Appl. No.: 11/349,654

(22) Filed: Feb. 7, 2006

(30) Foreign Application Priority Data
Feb. 25, 2005 (KR) 10-2005-0016030

(51) Int. Cl. H05K 1/03; H05K 3/02

(52) U.S. Cl. 174/255; 174/250; 29/847; 29/846

(57) ABSTRACT

The present invention relates to a flip chip ball grid array board, in which a thin unclad type core and a semi-additive process are used to form a circuit pattern, thereby providing a highly dense circuit pattern and an ultrathin core, and to a method of fabricating such a flip chip ball grid array board.

### INCORPORATION BY REFERENCE

The present application claims priority under 35 U.S.C. §119 to Korean Patent Application No. 10-2005-0016030 filed on Feb. 25, 2005. The content of the application is incorporated herein by reference in its entirety.

### BACKGROUND OF THE INVENTION

1. Field of the Invention

The present invention relates to a printed circuit board, more specifically a flip chip ball grid array board (FC-BGAB) and a fabrication method thereof, and more particularly, to an FC-BGAB, in which a thin unclad type core and a semi-additive process are used for the formation of a circuit pattern, thereby providing a highly dense circuit pattern and an ultrathin core, and to a method of fabricating a printed circuit board, particularly an FC-BGAB.

2. Description of the Related Art

Recently, with the great improvement in performance of semiconductor devices, a packaging substrate is required to have performance corresponding thereto. Typically, there is need for packaging substrates designed to have high densities, high speeds and reduced sizes, and further to realize systems in packaging.

Such a packaging substrate is exemplified by an FC-BGAB, which should have fine circuit patterns, high electrical properties, high reliability, and high-speed signal transfer structures and be ultrathin, depending on the requirements of semiconductor devices.

For example, according to technical trends of FC-BGABs in 2007, an FC-BGAB is predicted to have a thickness of 0.2 mm and a circuit pattern having an L/S of 10 μm/100 ∞m, in which L means lines, defining the width of the line, and S means spaces between the lines.

FIGS. 1A to 1H are sectional views sequentially showing a process of fabricating a conventional FC-BGAB, and FIG. 2 is a sectional view showing the problem of the conventional FC-BGAB.

As shown in FIG. 1A, both surfaces of an insulating layer 11 composed of a reinforcing material and a resin are coated with copper foils 12, 12′ to prepare a copper clad laminate (CCL) 10.

As shown in FIG. 1B, a via hole a is processed through the CCL 10 to connect circuits of upper and lower copper foils 12, 12′ of the CCL 10.

As shown in FIG. 1C, in order to electrically connect the formed via hole a, electroless copper plated layers 13, 13′ are formed on the upper and lower copper foils 12, 12′ of the CCL 10 and the inner wall of the via hole a in the CCL 10.

As shown in FIG. 1D, copper electroplated layers 14, 14′ are formed on the electroless copper plated layers 13, 13′ on the upper and lower copper foils 12, 12′ of the CCL 10 and the inner wall of the via hole a in the CCL 10.

As shown in FIG. 1E, the via hole a having the plated inner wall is filled with a conductive paste 15 so as not to have voids therein.

As shown in FIG. 1F, dry films 20, 20′ are applied on the upper and lower copper electroplated layers 14, 14′, exposed, and developed, to form an etching resist pattern.

As shown in FIG. 1G, the CCL 10, which has dry films 20, 20′ serving as etching resists, is dipped into an etchant, thereby removing the portions of the upper and lower copper foils 12, 12′, the electroless copper plated layers 13, 13′, and the copper electroplated layers 14, 14′, with the exception of the portions corresponding to predetermined patterns of the dry films 20, 20′.

As shown in FIG. 1H, the dry films 20, 20′ are removed from the upper and lower surfaces of the CCL 10, thus preparing the core of a conventional FC-BGAB.

Such a method of fabricating an FC-BGAB is disclosed in Korean Patent No. 190622, filed on Nov. 14, 1995, by the present applicant.

However, since the conventional FC-BGAB uses the thick CCL 10 as the core, it has a totally increased thickness and is thus difficult to manufacture into an ultrathin substrate having a thickness of 0.2 mm or less.

Further, the conventional FC-BGAB is disadvantageous because the side surface of the circuit pattern is etched along the total thicknesses of the copper foils 12, 12′, the electroless copper plated layers 13, 13′, and the copper electroplated layers 14, 14′, in the etching process shown in FIG. 1G. Thus, the conventional FC-BGAB has the actual circuit pattern shown in FIG. 2.

Therefore, in the conventional FC-BGAB, the US of the circuit pattern of the core is not actually formed into 50 μm/50 μm or less.

Consequently, the upper and lower circuit patterns of the core of the conventional FC-BGAB are difficult to manufacture, and the conventional FC-BGAB thus cannot satisfy high densities, high speeds, or reduced sizes, and is thus unsuitable for use in systems in packaging.

Moreover, it is certainly noted that the above difficulties are applied to all kinds of printed circuit board as well as FC-BGAB.

### SUMMARY OF THE INVENTION

Accordingly, the present invention has been made keeping in mind the above problems occurring in the related art, and an object of the present invention is to provide a printed circuit board, particularly an FC-BGAB, having a highly dense circuit pattern and an ultrathin core.

Another object of the present invention is to provide a method of manufacturing such an FC-BGAB.

In order to achieve the above objects, the present invention provides an FC-BGAB, including a core, the core having a base substrate having a surface roughness and including a reinforcing material and a resin; an electroless plated layer formed in a predetermined pattern on the base substrate; and an electroplated layer formed on the electroless plated layer.

In the FC-BGAB of the present invention, the base substrate is preferably an unclad type insulator, which includes the reinforcing material and the resin.

In the FC-BGAB of the present invention, the base substrate preferably includes the unclad type insulator, which includes the reinforcing material and the resin, and resin layers able to have roughness and applied on both surfaces of the unclad type insulator.

Further, the present invention provides a method of fabricating an FC-BGAB, including the steps of providing a base substrate including a reinforcing material and a resin; forming roughness on the base substrate; forming an electroless plated layer on the base substrate having surface roughness; forming a predetermined plating resist pattern on the electroless plated layer; forming an electroplated layer on the electroless plated layer, corresponding to the portion where the plating resist pattern is not formed; removing the plating resist pattern; and removing the electroless plated layer, corresponding to the portion

In the method of fabricating the FC-BGAB of the present invention, the providing step is preferably realized by providing an unclad type insulator, which includes the reinforcing material and the resin, as the base substrate, and step of forming roughness is preferably realized by forming roughness on the unclad type insulator.

In the method of fabricating the FC-BGAB of the present invention, the providing step is preferably realized by providing the unclad type insulator, which includes the reinforcing material and the resin, and resin layers able to have roughness and applied on both surfaces of the unclad type insulator, as the base substrate, and step of forming roughness is preferably realized by forming roughness on the resin layers able to have roughness.

### BRIEF DESCRIPTION OF THE DRAWINGS

FIGS. 1A to 1H are sectional views sequentially showing a process of fabricating a conventional FC-BGAB;

FIG. 2 is a sectional view showing the problem with the conventional FC-BGAB;

FIGS. 3A to 3H are sectional views sequentially showing a process of fabricating an FC-BGAB, according to an embodiment of the present invention; and

FIGS. 4A to 4H are sectional views sequentially showing a process of fabricating an FC-BGAB, according to another embodiment of the present invention.

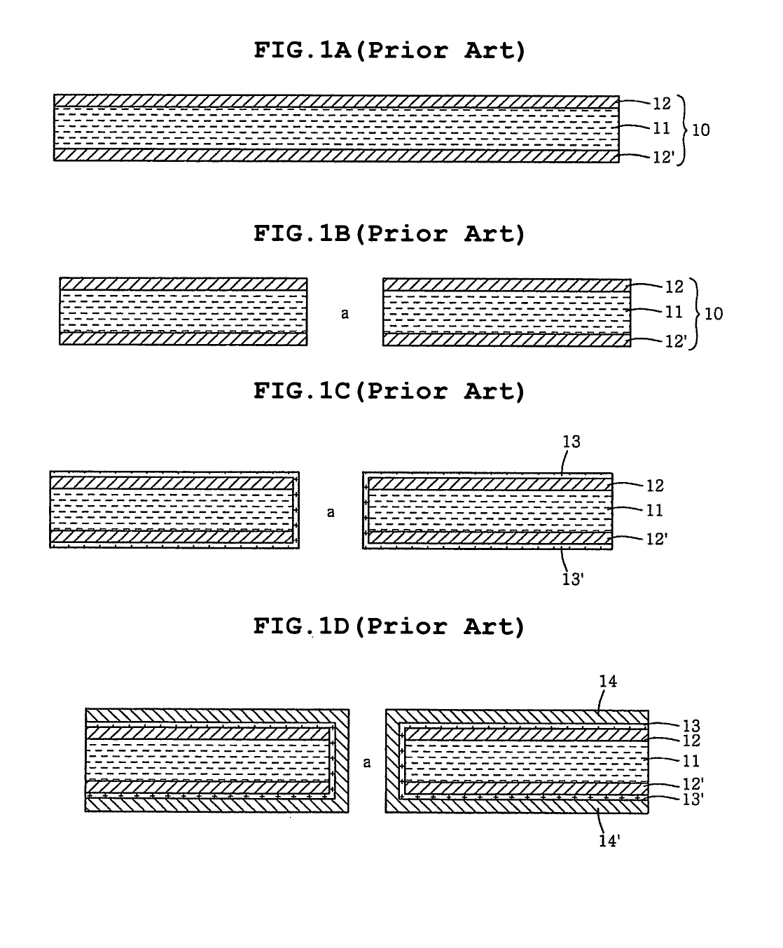

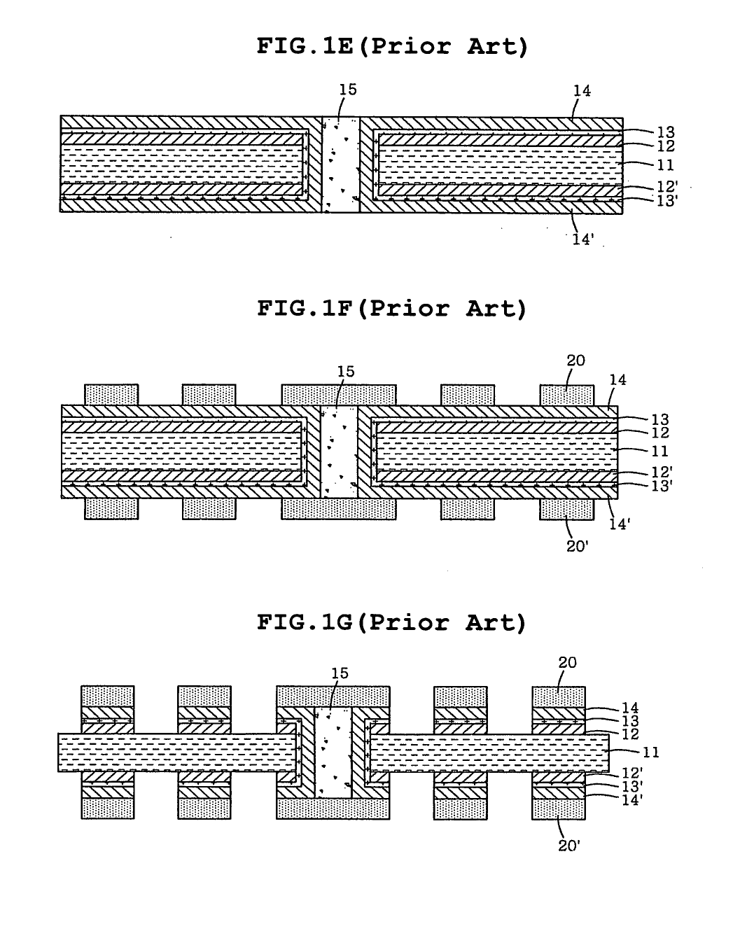

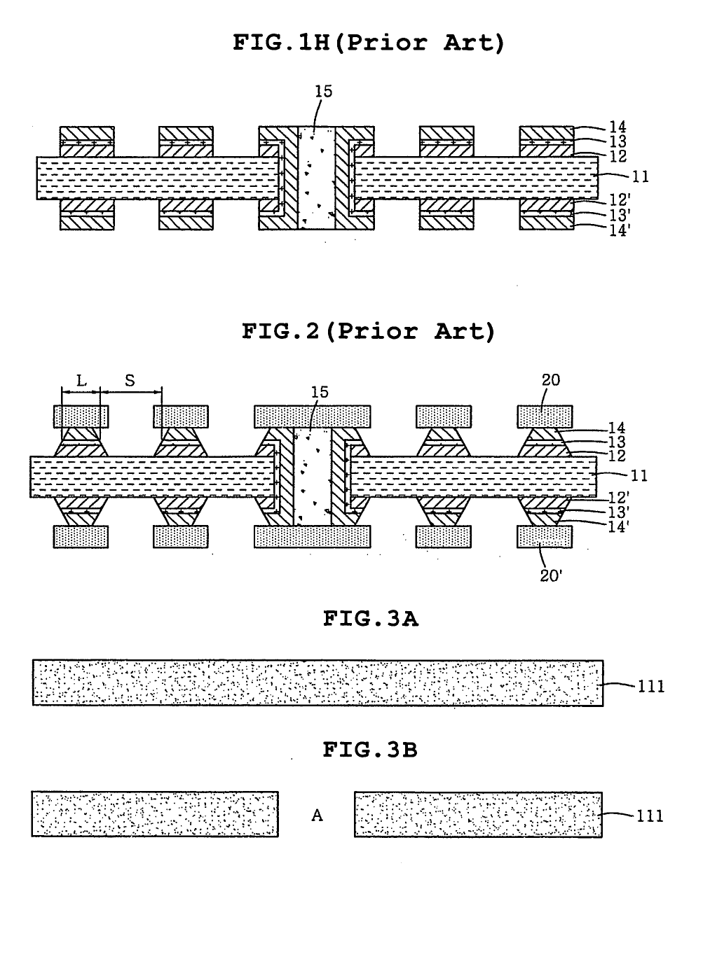

### DETAILED DESCRIPTION OF THE INVENTION

Hereinafter, a detailed description will be given of an FC-BGAB and a fabrication method thereof, according to the present invention, with reference to the appended drawings.

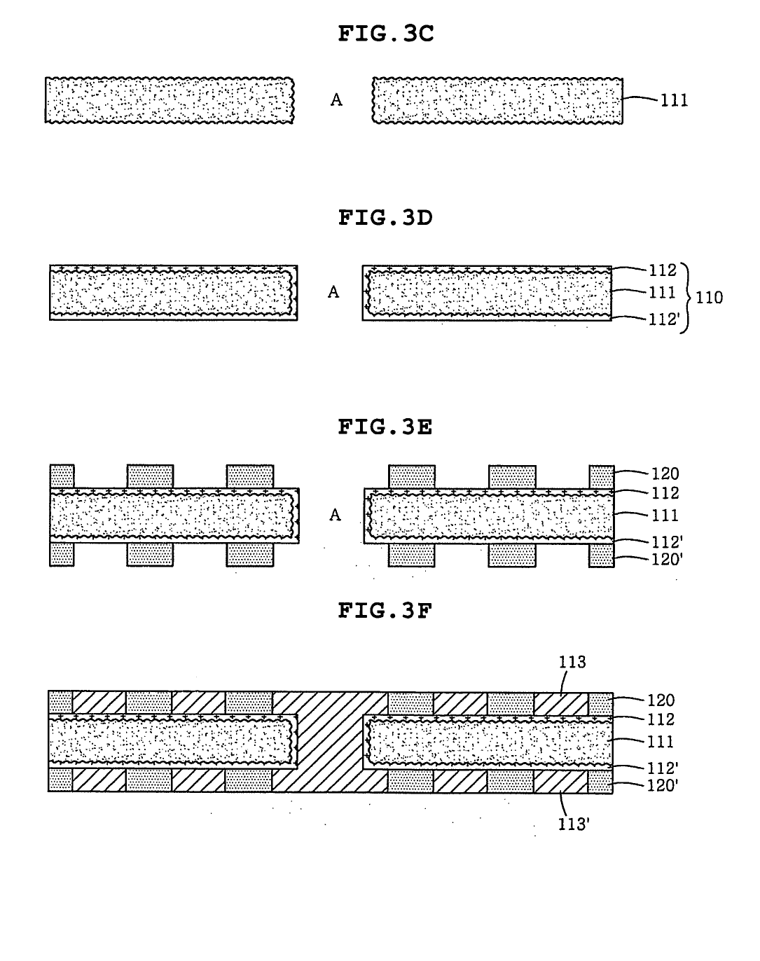

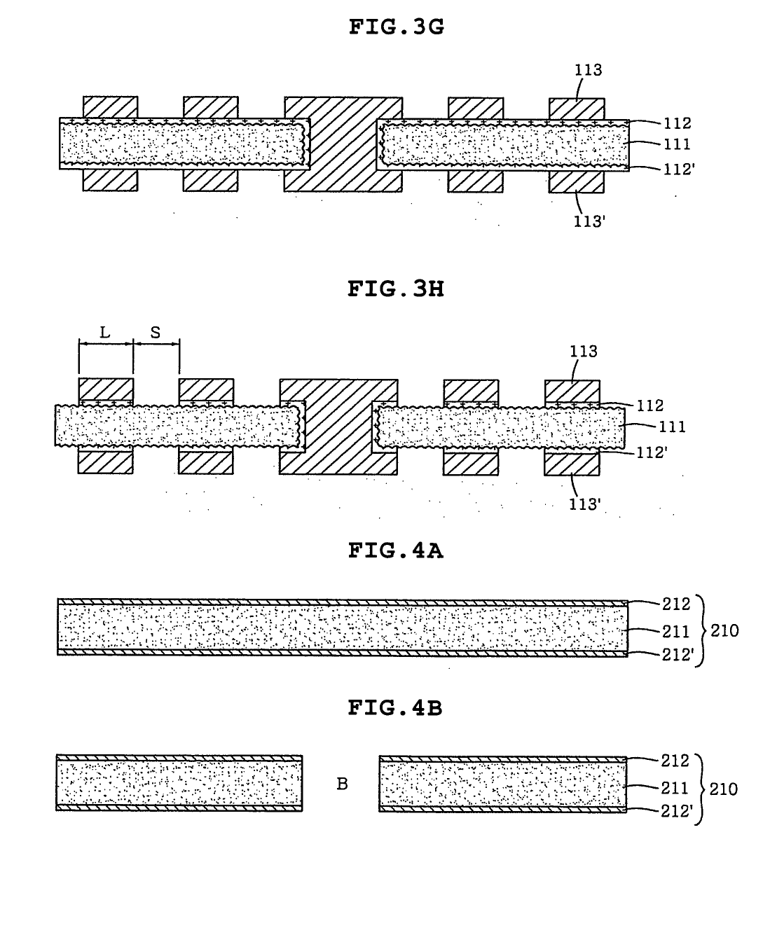

FIGS. 3A to 3H are sectional views sequentially showing a process of fabricating an FC-BGAB, according to an embodiment of the present invention.

As shown in FIG. 3A, an ultrathin unclad type insulator 111 is prepared.

The unclad type insulator 111 is preferably composed of a resin in which a reinforcing material is included, the resin being exemplified by epoxy resin, polyimide, and BT (Bismaleimide Triazine) resin, the reinforcing material being exemplified by glass fiber, aramid, and paper.

If a resin having no reinforcing material is used as the unclad type insulator 111, a problem of not satisfying physical properties necessary for a core, such as strength, hardness and a thermal expansion rate, may result.

As shown in FIG. 3B, a via hole A is formed through the unclad type insulator 111 to connect upper and lower circuits of the unclad type insulator 111.

The via hole A is preferably formed in a manner such that a via hole A is formed in a pre-set position using a CNC (Computer Numerical Control) drill or laser drill.

As show in FIG. 3C, the upper and lower surfaces of the unclad type insulator 111 and the inner wall of the via hole A undergo surface treatment for the formation of roughness, to increase adhesion with copper in a subsequent copper plating process.

The surface treatment is conducted using a chemical process (e.g., a desmearing process), a plasma process, or a CMP (Chemical Mechanical Polishing) process.

As shown in FIG. 3D, in order to electrically connect the upper and lower surfaces of the unclad type insulator 111 and form a circuit pattern on the unclad type insulator 111, electroless copper plated layers 112, 112′, acting as a seed layer, are formed on the upper and lower surfaces of the unclad type insulator 111 and the inner wall of the via hole A in the unclad type insulator 111.

The electroless copper plated layers 112, 112′ are formed using a catalyst deposition process or a sputtering process.

Specifically, the electroless copper plated layers 112, 112′ are formed on both surfaces of the unclad type insulator 111 and the inner wall of the via hole A in the unclad type insulator 111, through catalyst deposition including the steps of cleaning, soft etching, pre-catalysis, catalysis, acceleration, electroless copper plating, and oxidation prevention.

Alternatively, the electroless copper plated layers 112, 112′ may be formed on both surfaces of the unclad type insulator 111 and the inner wall of the via hole A in the unclad type insulator 111, through sputtering, in which ion particles (e.g., Ar⁺) of gas generated by plasma collide with a copper target.

As shown in FIG. 3E, plating resist patterns 120, 120′, corresponding to circuit patterns, are formed on the upper and lower electroless copper plated layers 112, 112′.

The plating resist patterns 120, 120′ are formed using a dry film or photosensitive liquid.

The dry film or photosensitive liquid is applied on the electroless copper plated layers 112, 112′. Subsequently, by the use of a photo mask having a predetermined pattern, the dry film or photosensitive liquid is exposed and developed, thereby forming the dry film or photosensitive liquid into the plating resist patterns 120, 120′.

As such, the use of photosensitive liquid is more preferable because the photosensitive liquid is applied to be thinner than the dry film, thus forming a finer circuit pattern. In addition, in the case where the surfaces of the upper and lower electroless copper plated layers 112, 112′ are irregular, they may be uniformly filled with the photosensitive liquid.

As shown in FIG. 3F, copper electroplated layers 113, 113′ are formed on the upper and lower electroless copper plated layers 112, 112′ and in the via hole A, corresponding to the portions where the plating resist patterns 120, 120′ are not formed.

The copper electroplated layers 113, 113′ are formed in a manner such that the substrate is dipped into a copper electroplating bath to conduct copper electroplating using a direct current (DC) rectifier. As such, the copper electroplating process is preferably conducted by calculating the plating area and then applying a predetermined current required to plate the calculated plating area using the DC rectifier to deposit copper.

The copper electroplating process is advantageous because the copper electroplated layers have physical properties superior to the electroless copper plated layers 112, 112′, and are easily formed to be thick.

As copper plating wires for use in the formation of the copper electroplated layers 113, 113′, a separately formed copper plating wire may be used. Alternatively, the electroless copper plated layers 112, 112′ are preferably used as the copper plating wires for the formation of the copper electroplated layers 113, 113′.

As shown in FIG. 3G, the plating resist patterns 120, 120′ are removed.

As shown in FIG. 3H, a flash etching process for spraying an etchant on the substrate is conducted, thereby removing the electroless copper plated layers 112, 112′, corresponding to the portions where the copper electroplated layers are not formed.

Thereafter, the procedures for laminating an insulating layer, forming a via hole A, forming electroless copper plated layers 112, 112′, and forming copper electroplated layers 113, 113′ are repeatedly carried out until the desired number of layers is obtained. Subsequently, the procedures for forming a solder resist, plating with nickel/gold, and forming an outline are additionally carried out, thus fabricating a desired FC-BGAB, according to the present embodiment of the invention.

In the FC-BGAB fabricated according to the present embodiment, since the plating resist patterns 120, 120′ are formed using light traveling straight, as shown in FIG. 3E, the side surfaces of the plating resist patterns 120, 120′ are perpendicular to the electroless copper plated layers 112, 112′. Accordingly, the side surfaces of the copper electroplated layers 113, 113′ are also perpendicular to the electroless copper plated layers 112, 112′, as shown in FIG. 3G.

In the FC-BGAB according to the present embodiment, since very thin electroless copper plated layers 112, 112′ are etched, as shown in FIG. 3H, side etching of upper and lower circuit patterns of the core occurs only very slightly.

Thus, the FC-BGAB according to the present embodiment can have a circuit pattern of the core, having an L/S of 10 μm/10 μm or less, in which L means lines, defining the width of the line, and S means spaces between the lines.

Further, the FC-BGAB according to the present embodiment can be fabricated to have a thickness of 0.2 mm or less, thanks to the use of the ultrathin unclad type insulator 111 to form the core, as is apparent from FIG. 3A.

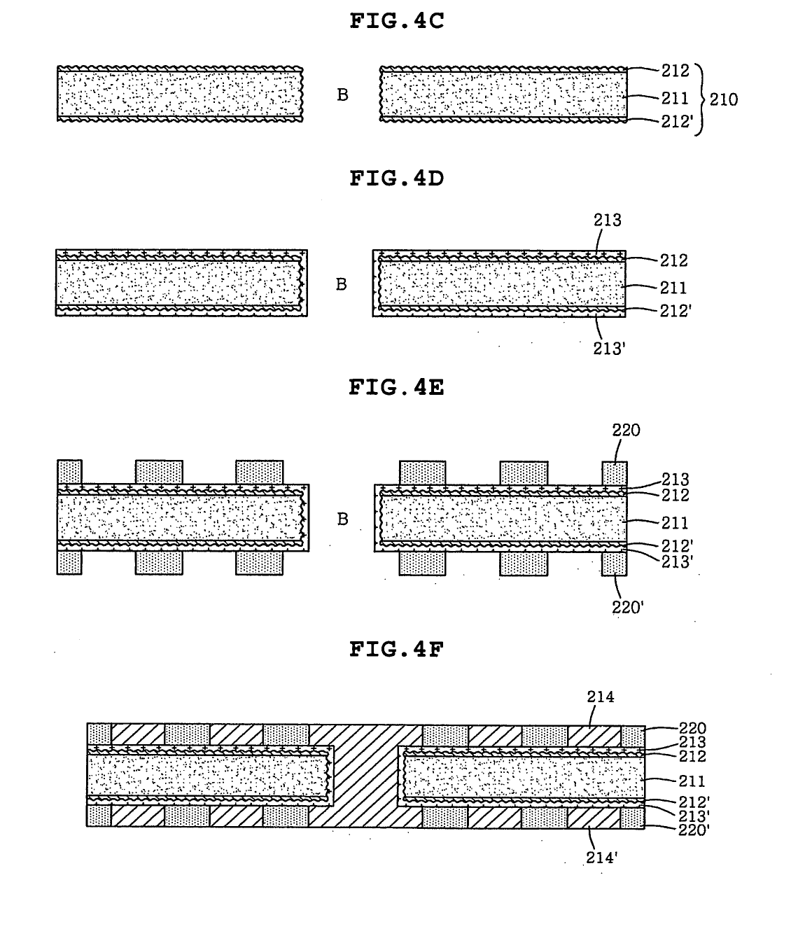

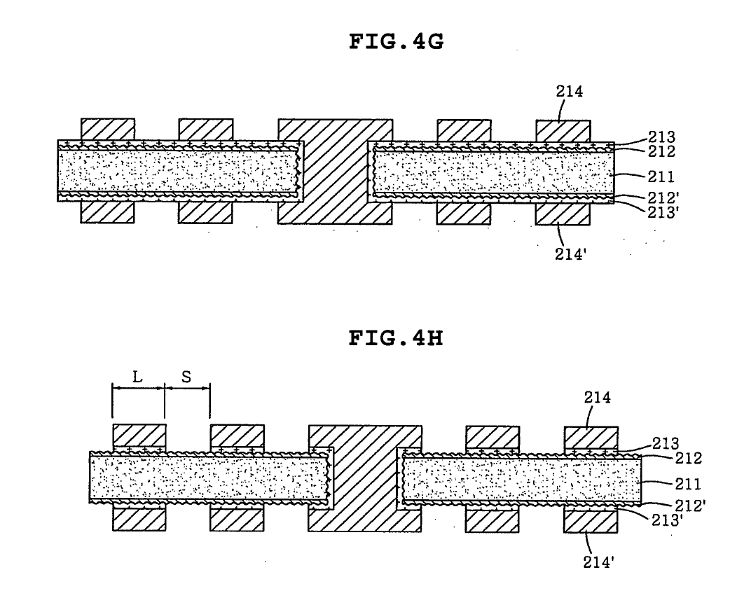

Turning now to FIGS. 4A to 4H, sectional views sequentially showing a process of fabricating an FC-BGAB according to another embodiment of the present invention are shown. In the process of fabricating the FC-BGAB, an unclad type insulator unable to have surface roughness is used to form a core.

As shown in FIG. 4A, a base substrate 210, which includes an ultrathin unclad type insulator 211 and resin layers 212, 212′ able to have surface roughness and applied on both surfaces thereof, is prepared.

The unclad type insulator 211 preferably includes a resin in which a reinforcing material is included, the resin being exemplified by epoxy resin, polyimide, and BT resin, the reinforcing material being exemplified by glass fiber, aramid, and paper.

The resin layers 212, 212′ able to have roughness are formed of ABF (Ajinomoto Built-up Film) or polyimide.

As shown in FIG. 4B, a via hole B is formed through the base substrate 210 to connect upper and lower circuits of the base substrate 210.

The via hole B is formed in a manner such that a via hole B is formed in a pre-set position using a CNC drill or a laser drill.

As show in FIG. 4C, the surfaces of the resin layers 212, 212′ able to have roughness and the inner wall of the via hole B, undergo surface treatment for the formation of roughness, so as to improve adhesion with copper in a subsequent copper plating process.

The surface treatment is conducted using a chemical process (e.g., a desmearing process), a plasma process, or a CMP process.

As shown in FIG. 4D, with the goal of electrically connecting the upper and lower surfaces of the base substrate 210 and forming a circuit pattern on the base substrate 210, electroless copper plated layers 213, 213′, acting as seed layers, are formed on the surfaces of the resin layers 212, 212′ able to have roughness, and the inner wall of the via hole B.

The electroless copper plated layers 213, 213′ are formed using a catalyst deposition process or a sputtering process.

As shown in FIG. 4E, plating resist patterns 220, 220′, corresponding to circuit patterns, are formed on the surfaces of the resin layers 212, 212′ able to have roughness.

The plating resist patterns 220, 220′ are formed using a dry film or photosensitive liquid.

As shown in FIG. 4F, copper electroplated layers 214, 214′ are provided on the surfaces of the resin layers 212, 212′ able to have upper and lower roughness and in the via hole B, corresponding to the portions where the plating resist patterns 220, 220′ are not formed.

The copper electroplated layers 214, 214′ are formed in a manner such that the substrate is dipped into a copper electroplating bath to conduct copper electroplating using a DC rectifier. The copper electroplating process is preferably conducted by calculating the plating area and then applying a predetermined current required to plate the calculated plating area using the DC rectifier, to deposit copper.

As shown in FIG. 4G, the plating resist patterns 220, 220′ are removed.

As shown in FIG. 4H, a flash etching process for spraying an etchant on the substrate is conducted, thereby removing the electroless copper plated layers 213, 213′, corresponding to the portions where the copper electroplated layers are not formed.

Then, the procedures for laminating an insulating layer, forming a via hole B, forming electroless copper plated layers 213, 213′, and forming copper electroplated layers 214, 214′ are repeatedly performed until the desired number of layers is obtained. Thereafter, the procedures for forming a solder resist, plating with nickel/gold, and forming an outline are additionally performed, thus fabricating a desired FC-BGAB, according to the present embodiment of the invention.

In the FC-BGAB fabricated according to the present embodiment, since the resin layers 212, 212′ made of ABF or polyimide to form roughness are used, a circuit pattern of the core, having an L/S of 10 μm/10 μm or less, in which L means lines, defining the width of the line, and S means spaces between the lines, may be formed even on the thin unclad type insulator 211 unable to have roughness.

In another embodiment, the copper plated layer of the FC-BGAB of the present invention is not limited to a plated layer consisting completely of pure copper, but means a plated layer consisting mainly of copper. This can be checked by analyzing the chemical composition of the copper plated layer using an analyzing device, such as EDAX (Energy Dispersive Analysis of X-rays), typically provided to a scanning electron microscope.

Further, in the present embodiment, the plated layer of the FC-BGAB of the present invention may be formed of a conductive material, such as gold (Au), nickel (Ni), tin (Sn), etc., depending on the end purpose, in addition to copper (Cu).

Meanwhile, the above embodiments are mainly described with an FC-BGAB as a matter of convenience. It is however evident that the present invention's feature applies to most printed circuit boards including an FC-BGAB. In other words, various modified embodiments can be made with respect to all printed circuit boards in which a thin unclad type core and a semi-additive process are used for the formation of a circuit pattern, thereby providing a highly dense circuit pattern and an ultrathin core.

As described above, the present invention provides an FC-BGAB and a fabrication method thereof. According to the FC-BGAB and the fabrication method thereof, since a thin unclad type core and a semi-additive process are used for the formation of a circuit pattern, a highly dense circuit pattern and an ultrathin core can be provided.

In addition, according to the FC-BGAB and the fabrication method thereof, a resin able to have roughness can be applied on the unclad type insulator. Hence, even though the thin unclad type insulator unable to have roughness is used, a core having a highly dense circuit pattern can be provided.

Therefore, the FC-BGAB of the present invention can correspond to high densities, high speeds, and reduced sizes, and can be further applied to systems in packaging.

Although the embodiments of the present invention has been disclosed for illustrative purposes, those skilled in the art will appreciate that various modifications, additions and substitutions are possible, without departing from the scope and spirit of the invention as disclosed in the accompanying claims.

What is claimed is:

1. A flip chip ball grid array board, comprising:
a core comprising:
a base substrate having surface roughness;
a reinforcing material; and
a resin;
an electroless plated layer formed in a predetermined pattern on the base substrate; and
an electroplated layer formed on the electroless plated layer.

2. The board as set forth in claim 1, wherein the base substrate is an unclad type insulator.

3. The board as set forth in claim 1, wherein the base substrate comprises:
an unclad type insulator having the reinforcing material and the resin; and
resin layers having roughness applied on both surfaces of the unclad type insulator.

4. A method of fabricating a flip chip ball grid array board, comprising steps of:
providing a base substrate including a reinforcing material and a resin;
forming roughness on the base substrate;
forming an electroless plated layer on the base substrate having surface roughness;
forming a predetermined plating resist pattern on the electroless plated layer;
forming an electroplated layer on the electroless plated layer, corresponding to a portion where the plating resist pattern is not formed;
removing the plating resist pattern; and
removing the electroless plated layer, corresponding to a portion where the electroplated layer is not formed.

5. The method as set forth in claim 4, wherein the providing step is realized by providing an unclad type insulator, which includes the reinforcing material and the resin, as the base substrate, and
the forming roughness step is realized by forming roughness on the unclad type insulator.

6. The method as set forth in claim 4, wherein the providing step is realized by providing the unclad type insulator, which includes the reinforcing material and the resin, and resin layers able to have roughness and applied on both surfaces of the unclad type insulator, as the base substrate, and
the forming roughness step is realized by forming roughness on the resin layers able to have roughness.

7. A printed circuit board, comprising:
a core comprising:
a base substrate having surface roughness;
a reinforcing material; and
a resin;
an electroless plated layer formed in a predetermined pattern on the base substrate; and
an electroplated layer formed on the electroless plated layer.

8. The printed circuit board as set forth in claim 7, wherein the base substrate is an unclad type insulator.

9. The printed circuit board as set forth in claim 7, wherein the base substrate comprises:
an unclad type insulator, having the reinforcing material and the resin; and
resin layers able to have roughness and applied on both surfaces of the unclad type insulator.
